(19) United States
(12) Patent Application Publication
(10) Pub. No.: US 2014/0263584 A1
(43) Pub. Date: Sep. 18, 2014

(54) WIRE BONDING APPARATUS AND METHOD

(71) Applicants: Jia Lin Yap, Klang (MY); Yin Kheng Au, Petaling Jaya (MY); Poh Leng Eu, Petaling Jaya (MY); Hung Yang Leong, Kota Damansara (MY); Mohd Rusli Ibrahim, Shah Alam (MY); Navas Khan Oratti Kalandar, Subang Jaya (MY); Mohd Faizal Zul-Kifli, Ipoh (MY)

(72) Inventors: Jia Lin Yap, Klang (MY); Yin Kheng Au, Petaling Jaya (MY); Poh Leng Eu, Petaling Jaya (MY); Hung Yang Leong, Kota Damansara (MY); Mohd Rusli Ibrahim, Shah Alam (MY); Navas Khan Oratti Kalandar, Subang Jaya (MY); Mohd Faizal Zul-Kifli, Ipoh (MY)

(21) Appl. No.: 13/794,836

(22) Filed: Mar. 12, 2013

(51) Int. Cl. H01L 23/00

(52) U.S. Cl. CPC H01L 24/85; H01L 24/78
USPC 228/180.5; 228/4.5

(57) ABSTRACT

A method of making an electrical connection includes passing a bond wire through a wire bonding system having a wire polisher and a wire bonding tool. The wire polisher removes contamination from a first portion of the bond wire. A first bond is then formed by bonding the first portion of the bond wire to a first contact such that the bond wire and the first device are electrically connected. A second bond is then formed by bonding a second portion of the bond wire to a second contact such that the first contact and the second contact are electrically connected.

### BACKGROUND OF THE INVENTION

The present invention is directed to semiconductor packaging and, more particularly, to an apparatus and method for wire bonding bare and insulated wires.

An integrated circuit (IC) die is a small device formed on a semiconductor wafer, such as a silicon wafer. Such a die is typically cut from the wafer and attached to a substrate or base carrier for interconnect redistribution. Bond pads on the die are electrically connected to carrier leads on the substrate with wires via wire bonding. That is, a wire bonding apparatus attaches a first end of a bond wire with a first bond at the die bond pad and attaches a second end of the bond wire with a second bond at the carrier lead. Wires also may be used to cross connect bond pads of the die or to cross connect leads of the substrate. The die, wires and substrate are then encapsulated to form a packaged device.

There is a continuing demand for more dense ICs, yet without a corresponding increase in the size or footprint of the packaged device. There is also a desire for more inputs and outputs to ICs, resulting in high densities of interconnections between the IC die and the substrate, and the need for fine pitch and ultra-fine pitch wire bonding. The diameter of the bond wire also has decreased. For example, 63 um pitch applications use 25 um diameter wire, while 52 um and 44 um pitch applications use 20.3 um diameter wire. Development is being done for a 37 um pitch application using 17 um diameter wire.

Bond wire used to make such interconnections may be bare or uncoated metal wires, such as bare or uncoated copper wire. Alternatively, bond wire may be formed of insulated or coated metal wires.

Bare copper wire is economical and exhibits electrical properties, such as self inductance and self capacitance, similar to that of gold, which is a more expensive alternative.

Insulated or coated wires are also beneficial for decreasing wire sweep and wire shorts. Specifically, decreases in pitch and wire diameter cause difficulties in handling and wire bonding. For example, wires may unintentionally short to other conductive structures of the packaged device, such as other wires, pads, leads, or the die. This shorting may occur during the encapsulation process as, for example, from “sweeping,” where the injection or transfer of the liquid molding encapsulant moves the wires against another conductive structure. Parts that use smaller diameter wires tend to have higher wire sweep rejects. However, wires formed of a conductive core insulated or covered by an organic material are effective for decreasing these negative effects.

However, both of these types of bond wires also have some drawbacks in conventional wire bonding apparatuses and methods. Specifically, the surface of bare copper wire is susceptible to contamination by oxidation, which results in the formation of copper oxides on the surface of the copper bond wire. These contaminants, namely copper oxides, adversely affect the bond formation and strength at the first and second bonds. For example, non-stick on the pad (NSOP), non-stick on the lead (NSOL) and short tail defects are common problems associated with surface oxide contamination of bare copper wires. Thus, bare or uncoated copper bond wire has a relatively short shelf life for these types of interconnection applications, specifically 5-7 days.

Insulated or coated wires are not typically subject to such contamination, but it is difficult to obtain good quality bonds when using coated wires, especially for the second bond (i.e., the stitch bond). NSOL is a common problem associated with insulated wires because the wire insulation between the wire and the lead prevents good adhesion.

The weak adhesion is evidenced in wire peel test results. In a wire peel test, a hook is placed under the wire proximate to the second bond and a lifting force is applied, thereby testing the strength of the second bond adhesion to the lead/post. Insulated fine wire and insulated ultra-fine wire usually exhibit very low wire peel strength. To increase the peel strength, insulated wires must typically be subject to a high degree of scrubbing, but this often leads to a decrease in throughput for the bonding process.

Accordingly, it would be advantageous to provide an apparatus and method for wire bonding both bare and insulated wires that results in improved bond quality of the first and second bonds while also maintaining a high level of throughput.

### BRIEF DESCRIPTION OF THE DRAWINGS

The present invention is illustrated by way of example and is not limited by embodiments thereof shown in the accompanying figures, in which like references indicate similar elements. Elements in the figures are illustrated for simplicity and clarity and have not necessarily been drawn to scale. Notably, certain vertical dimensions have been exaggerated relative to certain horizontal dimensions.

FIG. 1 is a schematic view illustrating various exemplary configurations of a wire bonding apparatus in accordance with a first embodiment of the present invention;

FIG. 2A is an enlarged side elevational view of an electrical connection in accordance with the first embodiment of the present invention;

FIG. 2B is an enlarged side elevational view of an electrical connection in accordance with a second embodiment of the present invention;

FIG. 3 is perspective view of a wire polisher of the wire bonding apparatus in accordance with the first embodiment of the present invention;

FIG. 4 is a schematic view illustrating an exemplary configuration of a wire bonding apparatus in accordance with the second embodiment of the present invention; and

FIG. 5 a cross-sectional view of an insulated wire for use in the second embodiment of the present invention.

### DETAILED DESCRIPTION OF THE INVENTION

Referring to the drawings, wherein the same reference numerals are used to designate the same components throughout the several figures, there is shown in FIG. 1 a wire bonding system or wire bonding apparatus 10 in accordance with a first embodiment of the invention. FIG. 4 shows a wire bonding system or wire bonding apparatus 110 in accordance with a second embodiment of the invention.

The wire bonding apparatus 10, 110 is used to electrically connect a first device 26 to a second device 28 with a bond wire 30, 130, prior to encapsulation, as shown in FIGS. 2A-2B. The first device 26 may be a semiconductor die such as an IC formed on a silicon substrate. The second device 28 may also be a semiconductor die, such as a bottom or lower die in a stacked die configuration. However, in the presently preferred embodiment, the second device 28 is a carrier, substrate or lead frame.

More particularly, as shown in FIGS. 2A-2B, the bond wire 30, 130 electrically connects a first bonding pad 26a of the first device 26 to a second bonding pad or lead finger 28a of the second device 28, which in this case is a lead frame. The first and second devices 26, 28 and their respective bonding pads 26a, 28a are of a type known to those of ordinary skill in the art and detailed descriptions thereof are not necessary for a full understanding of the invention.

The connection of the bond wire 30, 130 at the first bonding pad 26a of the first device 26 is referred to herein as a first bond and the connection of the bond wire 30, 130 at the bonding pad 28a of the second device 28 is referred to herein as a second bond. In the presently preferred embodiment, the first bond is a ball bond and the second bond is a stitch bond.

The term “wire bonding” is generally accepted to mean the interconnection, via wire, of chips and substrates. The most frequently used methods of joining the wires to the pads are via either thermosonic or ultrasonic bonding. Ultrasonic wire bonding uses a combination of vibration and force to rub the interface between the wire and the bond pad, causing a localized temperature rise that promotes the diffusion of molecules across the boundary. Thermosonic bonding, in addition to vibration, uses heat, which further encourages the migration of materials.

In ball bonding, a capillary holds the wire. A free air ball (FAB) is formed on one end of the wire and is pressed against the face of the capillary. The FAB may be formed with a hydrogen flame or a spark. The capillary pushes the FAB against the first bonding pad, and then, while holding the FAB against the first pad, ultrasonic vibration is applied, which bonds the wire to the die, thus forming the first bond. Once the FAB is bonded to the first bonding pad, the capillary, which is still holding the wire, is moved over the second bonding pad to which the first bond pad is to be electrically connected. The wire is pressed against the second pad and once again ultrasonic energy is applied until the wire is bonded to the second pad, thus forming the second bond. The capillary is then lifted off the bond, breaking free from the wire. Both stitch bonding and ball bonding are well known by those of skill in the art.

In a first preferred embodiment, shown in FIG. 1, the wire bonding apparatus 10 includes a bond wire feed 12, and more particularly a spool 12 of bond wire 30, an air guide 14, a wire tensioner 16, a wire clamp 18, an electric flame off (EFO) device 20 and a wire bonding tool 22. The air guide 14 may be provided to ensure a smooth and continuous wire supply to the wire bonding tool 22. The tensioner 16 may supply a constant, pre-determined amount of tension to the bond wire 30 during predetermined timeframes of a wire bond cycle. The wire clamp 18 may releasably clamp the bond wire 30 and may be configured to move with the wire bonding tool 22, or independent of the wire bonding tool 22, to supply the bond wire 30 through the wire bonding tool 22 and/or to break the wire bonding tool 22 free from the bond wire 30 after the second bond (e.g., a stitch bond) is made.

The bond wire 30 may be removably inserted through the wire bonding tool 22, such that a ball formed at an end of the bond wire 30 by the EFO device 20 (i.e., a free air ball) projects from the wire bonding tool 22. Specifically, the EFO device 20 generates a spark on the end of the bond wire 30 to produce such the FAB. After the FAB is formed, the above-described ball bonding and stitch bonding processes are carried out.

It will be understood that the present invention is not limited to the particular configurations of the wire bonding apparatus 10 shown in FIG. 1. That is, various other configurations with some or all of the wire bonding apparatus components (i.e., air guide 14, tensioner 16, clamp 18 and wire bonding tool 22) may be provided in a different sequential order than that illustrated in FIG. 1.

The wire bonding apparatus 10 shown in FIG. 1 is particularly configured for use with bond wire 30 formed from a bare or uncoated metal wire, such as a bare wire of copper, copper alloys, silver, silver alloys, aluminum, aluminum alloys, and the like. In the presently preferred embodiment, the bond wire 30 is bare or uncoated copper wire.

The wire bonding apparatus 10 further includes a wire cleaning device or polisher 24. The wire polisher 24 is preferably removable from the wire bonding apparatus 10 and may be operationally disposed in the wire bonding path at any position between the wiring spool 12 and the wire bonding tool 22 to selectively remove contaminants, such as copper oxides, present on the surface of the bond wire 30 prior to the bond wire 30 entering the wire bonding tool 22.

For example, in an exemplary configuration shown in FIG. 1, the wire polisher 24 is positioned above the tensioner 16, and more particularly between the air guide 14 and the tensioner 16. In an alternative exemplary configuration, shown in phantom in FIG. 1, the wire polisher 24 is positioned below the tensioner 16, and more particularly between the tensioner 16 and the wire clamp 18. In another alternative exemplary configuration shown in phantom in FIG. 1, the wire polisher 24 is positioned below the wire clamp 18, and more particularly between the wire clamp 18 and the wire bonding tool 22.

The wire polisher 24 is preferably a mechanical polisher. More particularly, in the first embodiment, as shown in FIG. 1, the wire polisher 24 is a micro-polisher.

The wire bonding apparatus 10 preferably also includes a vacuum device 32 either incorporated within the micro-polisher 24 (as shown in solid lines FIG. 1) or positioned immediately thereafter in the wire bonding path (as shown in phantom in FIG. 1) which evacuates particles of removed contamination from the wire bonding apparatus 10. More particularly, in the exemplary embodiment, the vacuum device 32 is preferably a vacuum ultrasonic vibrator 32 which provides ultrasonic vibration to the bond wire 30 as it is being polished by the micro-polisher 24, or immediately thereafter, and generally simultaneously draws a vacuum to evacuate or remove any released residual contaminant particles from the wire bonding apparatus 10.

It will be appreciated that the micro-polisher 24 may have any appropriate configuration and structure, as long as it substantially or entirely circumferentially surrounds the bond wire 30 for removal of contaminants therefrom.

An enlarged view of an exemplary embodiment of the micro-polisher 24 is shown in FIG. 3. The micro-polisher 24 preferably has a generally cylindrical configuration, a first inner surface 24a configured to contact the bond wire 30, and a second opposed exterior surface 24b. In such an exemplary embodiment, the inner and outer surfaces 24a and 24b of the micro-polisher 24 form a generally tubular sidewall 34. The micro-polisher 24 further includes a first open end 36, a second opposing open end 38, and a cylindrical cavity 40 formed therebetween for receiving the bond wire 30. The diameter of the cylindrical cavity 40 (i.e., the inner diameter of the micro-polisher 24) is preferably only slightly larger than the outer diameter of the bond wire 30 to be received therethrough, so that successful micro-polishing of the bond wire 30 can be accomplished as it passes through the cavity 40 of the micro-polisher 24.

More particularly, in the exemplary embodiment, at least the inner contact surface 24a of the micro-polisher 24 is preferably formed of an abrasive material, such as ceramic, diamond grit, silica, carbide and like materials of similar abrasiveness. Preferably, the material of the contact surface 24a of the micro-polisher 24 is sufficiently abrasive to remove contaminants from the surface of the bond wire 30, without damaging the wire 30. Also, after passing though the micro-polisher 24, the surface of the bond wire 30 is preferably not only free of contaminants, but has also been polished to a generally smooth finish.

In an exemplary embodiment, as shown in FIGS. 1 and 3, the micro-polisher 24 is moveable from a first contracted position, in which the inner surface 24a of the micro-polisher 24 is in contact with the bond wire 30 for removal of surface contamination, to a second expanded position, in which the inner surface 24a of the micro-polisher 24 is out of contact with the bond wire 30, and vice versa. As such, in the exemplary embodiment, the inner diameter of the micro-polisher 24 can be selectively varied. Also, the micro-polisher 24 of the exemplary embodiment can be selectively contracted and expanded to polish and remove contamination from only select portions of the bond wire 30, while leaving other portions of the bond wire 30 unaltered or undisturbed.

In the exemplary preferred embodiment, the micro-polisher 24 is configured to remain in the expanded position throughout the wire bonding process and transition to the contracted position only as portions of the bond wire 30 which will be used to form the first bonds pass therethrough. In the exemplary embodiment, the micro-polisher 24 also transition to the contracted position as portions of the bond wire 30 which will be used to form the second bonds pass therethrough.

More particularly, the micro-polisher 24 is preferably in operative communication with a processor (not shown) which is programmed or configured to calculate the length of bond wire 30 necessary for the formation of each interconnect, identify which portions of the bond wire 30 along the calculated length will be used for form the first and second bonds, and prompt the micro-polisher 24 to move from the expanded position to the contracted position as the identified portions pass therethrough.

In an exemplary embodiment, illustrated in FIG. 3, the micro-polisher 24 preferably includes a longitudinal slit 42 extending from the first open end 36 to the second open end 38. As such, the micro-polisher 24 can be easily expanded (via the slit 42) and removed from the wire bonding apparatus 10 for cleaning and other maintenance activities.

The present invention also relates to a method of electrically connecting the first device 26 to the second device 28 using the wire bonding apparatus 10. The method includes the steps of feeding the bond wire 30 through the wire bonding apparatus 10 until the wire 30 extends through the bonding tool 22. As the bond wire 30 passes through the wire bonding apparatus 10, at least a first portion of the exterior surface of the bond wire 30 is micro-polished for the removal of surface contamination. The first portion corresponds to a portion of the bond wire 30 which the processor has determined will be used for formation of the first bond. Preferably, however, the micro-polisher 24 also removes contamination from a second portion of the bond wire 30 which the processor has determined will be used for formation of the second bond.

The cleaned first portion of the bond wire is then used to form a ball with a hydrogen flame or a spark. The ball is pressed against the first bonding pad 26a of the first device 26 by the bonding tool 22. Next, thermocompression, thermosonic or ultrasonic wire bonding is performed to form the first bond (i.e., a ball bond) which electrically connects the bond wire 30 and the first device 26.

The second bond is then similarly created by pressing the second cleaned portion of the wire 30 against the second bonding pad 28a of the second device 28 by the bonding tool 22, and performing thermocompression, thermosonic or ultrasonic wire bonding to bond the cleaned second portion of the bond wire 30 to the second bonding pad 28a of the second device 28 to form the second bond (i.e., a stitch bond). No free air ball is necessary for formation of the second bond. The first device 26 and the second device 28 are thereby electrically connected to each other. The bonding tool 22 is then lifted off the second bond pad 28a, which breaks the wire 30 at the bond.

Thus, according to the present invention, the portions of the bond wire 30 used for free air ball formation and the first and second bonds are polished or cleaned, meaning they are substantially or entirely devoid of surface contamination. Consequently, there is near elimination of rejection of parts due to NSOP and NSOL. Also, short tail defects are substantially or entirely prevented. The wire bonding apparatus 10 also increases the shelf life of the bond wire 30, since even wire which has begun oxidizing can still be utilized.

FIG. 4 shows a second embodiment of a wire bonding system or wire bonding apparatus 110 in accordance with the invention. The second embodiment is similar to the first embodiment described above. Like numerals have been used for like elements, except the 100 series numerals have been used for the second embodiment. Accordingly, a complete description of the second embodiment has been omitted, with only the differences being described.

The wire bonding apparatus 110 is particularly configured for use with an insulated or coated bond wire 130. A cross-sectional view of an exemplary insulated wire 130 is shown in FIG. 5. Referring to FIG. 5, the insulated bond wire 130 comprises a conductive metal core 144 circumferentially coated with a layer of an electrically insulating material 146, such as an organic coating. The insulated wire 130 is suitable for fine pitch and ultra-fine pitch wire bonding. The insulating material layer 146 prevents the insulated wire 130 from shorting to other wires or other conductive structures.

In general, gold and aluminum are the most commonly used elements to make the conductive core 144 of the bond wire 130. Both gold and aluminum are strong and ductile and have similar resistance in most environments. Gold wire is sometimes doped with a dopant, such as beryllium, calcium in order to stabilize it. Small-diameter aluminum wire is often doped with silicon or sometimes magnesium to improve its breaking load and elongation parameters. In addition to gold and aluminum, copper, palladium-alloy, platinum and silver bond wire are also known for making the conductive core of an insulated or coated bond wire.

As is known by those of skill in the art, various size wires are available for connecting dies to substrates, with the wire size being selected based on, among other things, pad pitch. The insulated wire 130 of the second embodiment of the present invention, has a diameter of between about 15 μm to about 55 μm, although other diameter bond wires may be used and the invention should not be limited to a particular bond wire diameter. In a preferred embodiment, the insulated wire 130 has a diameter of less than about 25 um. The insulative coating 146 preferably is an organic insulative coating having a thickness of about 0.1 um to about 2.0 um that can be thermally decomposed during free air ball formation. Further, the insulated wire 130 preferably has a melting temperature (Tg) of about 180° C. to 350° C.

In the embodiment of the present invention shown in FIG. 4, instead of a wire polisher 24, the wire bonding apparatus 110 is provided with a wire stripper 124.

The wire stripper 124 may be disposed in the wire bonding path at a position between the spool 112 of insulated wire 130 and the wire bonding tool 122 to selectively remove the insulation or coating 146 from portions of the insulated wire 130 and expose the underlying conductive core 144 prior to the insulated wire 130 entering the wire bonding tool 122.

The wire bonding apparatus 10 preferably also includes a vacuum device 132 either incorporated within the wire stripper 124 (as shown in solid lines FIG. 4) or positioned immediately thereafter in the wire bonding path (as shown in dotted lines in FIG. 4). In the exemplary embodiment, the vacuum device 132 draws a vacuum to evacuate or suction the stripped insulation material out from the wire bonding apparatus 110.

It will be understood that the wire stripper 124 may be operationally disposed anywhere between the wire spool 112 and the wire bonding tool 122. For example, in an exemplary embodiment shown in FIG. 4, the wire stripper 124 is positioned below the tensioner 116, and more particularly between the tensioner 116 and the wire clamp 118.

The wire stripper 124 is preferably a mechanical stripper. It will be understood that the wire stripper 124 may be any mechanical stripper capable of removing the insulation coating 146 from the conductive core 144 of the insulated wire 130. In an exemplary embodiment, the wire stripper 124 is preferably a micro-clipper including one or more cutting or stripping blades (not shown) which cut or clip at least a portion of the insulation 146 surrounding the conductive core 144. In another exemplary embodiment, the wire stripper 124 is a scrubber with an abrasive contact surface (not shown) configured to tear the bond wire insulation 146 away from the conductive core 144.

In an exemplary embodiment shown in FIG. 4, the wire stripper 124 removes the insulation material 146 from only select portions of the insulated wire 130, while leaving other portions of the insulated wire 130 undisturbed. More particularly, the wire stripper 124 removes some, and preferably all, of the insulation material 146 which surrounds the conductive core 144 at select portions of the insulated wire 130, such that at least a portion of the conductive metal core 144, and more preferably the entire conductive metal core 144, is exposed at the stripped portions of the insulated wire 130.

Preferably, the insulation material 146 is removed from portions of the bond wire 130 which will be used to form the second bonds. More preferably, the insulation material 146 is removed from portions of the bond wire 130 which will be used to form both the first and the second bonds.

In an exemplary embodiment, the wire stripper 124 is preferably in operative communication with a processor (not shown) which is configured to calculate the length of insulated wire 130 necessary for the formation of each interconnect and identify which portions of the insulated wire 130 along the calculated length will be used for formation of the second bonds. The processor is also configured to prompt operation of the wire stripper 124 to remove the insulation material 146 and at least partially expose the conductive core 144 of only the identified portions. Thus, during the subsequent wire bonding process, at least a portion of the conductive metal core 144 of the insulated wire 130 contacts the second bonding pad 28a of the second device 28 for formation of the second bond.

Preferably, the processor also identifies the portions of the insulated wire 130 which will be used to form the first bonds and prompts the wire stripper 124 to also remove the insulation material 146 from such portions of the insulated wire 130. Thus, during the subsequent wire bonding process, the free air ball at the first bond is formed of bare metal and at least a portion of the conductive metal core of the insulated wire 130 contacts the first bond pad 26a for formation of the first bond.

In an optional embodiment, the wire stripping device 124 may be heated with a local heat source (not shown) in order to increase the effectiveness of insulation cutting or tearing by the device 124.

The present invention also relates to a method of electrically connecting the first device 26 to the second device 28 using the wire bonding apparatus 110. The method includes the steps of feeding the insulated wire 130 through the wire bonding apparatus 110 until the insulated wire 130 extends through the bonding tool 122. As the insulated wire 130 passes through the wire bonding apparatus 110, a processor identifies which portions of the insulated wire 130 will be used to form the first bonds and which portions will be used to form the second bonds. The wire stripper 124 then strips or removes the insulation material 146 from at least the portions of the insulated wire 130 which will be used for formation of the second bonds, such that at least a portion of the underlying conductive metal core 144 is exposed. More preferably, however, the wire stripper 124 also strips or removes the insulation material 146 from the portions of the insulated wire 130 which will be used for free air ball formation of the first bonds, such that at least a portion of the underlying conductive metal core 144 is exposed.

The first bond (e.g., a ball bond) is then formed by forming a ball at one end of the insulated wire 130 with a hydrogen flame or a spark and pressing it against the first bonding pad 26a of the first device 26 by the bonding tool 122. Next, thermocompression, thermosonic or ultrasonic wire bonding is performed to bond the insulated wire 130 to the first bonding pad 26a of the first device 26. More preferably, the ball is formed from a stripped portion of the insulated wire 130, such that the exposed metal core 146 of the stripped portion is wire bonded to the first bonding pad 26a. The insulated wire 130 and the first device 26 are thus electrically connected.

The second bond (e.g., a stitch bond) is then formed by pressing a stripped portion of the wire 130 against the second bonding pad 28a of the second device 28 by the bonding tool 122, and performing thermocompression, thermosonic or ultrasonic wire bonding to bond the exposed metal core 146 of the stripped portion of the wire 130 to the second bonding pad 28a. The first device 26 and the second device 28 are thereby electrically connected to each other. The bonding tool 122 is then lifted off the bond pad 28a, which breaks the wire 130 at the bond.

The present invention has been found to provide the following advantages: (a) near elimination of rejection of parts due to NSOL at the second bond; (b) enhancing the bondability of insulated wire at the second bond with an increased wire pull/wire peel strength; (c) new or modified wire bonding equipment is not required except for the inclusion of a mechanical stripper in the wire bonding path; (d) wire shorting rejects at mold have been decreased; (e) an expensive mold compound having a very fine filler is not required; (f) the use of fine coated wire enables cross bonding; (g) the pad/die design rules do not need to be restricted to peripheral pads only; and (h) decrease in electrical open short rejects.

The description of the preferred embodiment of the present invention has been presented for purposes of illustration and description, but is not intended to be exhaustive or to limit the invention to the form disclosed. It will be appreciated by those skilled in the art that changes could be made to the embodiment described above without departing from the broad inventive concept thereof. The present invention is applicable to all wire bonded package types, including but not limited to Ball Grid Array (BGA), Tape Ball Grid Array (TBGA), Plastic Ball Grid Array (PBGA), Quad Flat No-lead (QFN), Quad Flat Package (QFP), Small Outline Integrated Circuit (SOIC), and chip scale package (CSP). In addition, uncoated or coated/insulated wires may also be used to connect other types of conductive structures in a packaged IC.

In the foregoing specification, the invention has been described with reference to specific examples of embodiments of the invention. It will, however, be evident that various modifications and changes may be made therein without departing from the broader spirit and scope of the invention as set forth in the appended claims.

The terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

In the claims, the word ‘comprising’ or ‘having’ does not exclude the presence of other elements or steps then those listed in a claim. Further, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The fact that certain measures are recited in mutually different claims does not indicate that a combination of these measures cannot be used to advantage.

1. A method of making an electrical connection, comprising:
passing a bond wire through a wire bonding system comprising a wire polisher and a wire bonding tool;
removing contamination from at least a first portion of the bond wire using the wire polisher;
forming a first bond by wire bonding the first portion of the bond wire to a first contact such that the bond wire and the first contact are electrically connected; and
forming a second bond by wire bonding a second portion of the bond wire to a second contact such that the first contact and the second contact are electrically connected.

2. The method of claim 1, wherein the contamination removing step comprises contacting an abrasive surface of the polishing device with an exterior surface of at least the first portion of the bond wire.

3. The method of claim 1, further comprising removing contamination from the second portion of the bond wire.

4. The method of claim 3, wherein the contamination is removed from the second portion of the bond wire by contacting an abrasive surface of the polishing device with an exterior surface of the second portion of the bond wire.

5. The method of claim 1, wherein the contamination is removed from substantially an entire surface of the bond wire by contacting an abrasive surface of the polishing device with an exterior surface of the bond wire.

6. The method of claim 1, wherein the bond wire is an uncoated metal wire.

7. The method of claim 6, wherein the bond wire is bare copper wire.

8. The method of claim 7, wherein the removed contamination comprises copper oxides.

9. The method of claim 1, wherein the first bond is a ball bond and the second bond is a stitch bond.

10. A wire bonding system, comprising:
a bond wire feeder to which a spool of bond wire may be coupled;
a wire bonding tool; and
a wire polisher positioned between the bond wire feeder and the wire bonding tool, the wire polisher being configured to remove contamination from the bond wire.

11. The wire bonding system of claim 10, wherein the wire polisher is a micro-polisher having at least one abrasive surface.

12. The wire bonding system of claim 11, further comprising a vacuum device proximate to the wire polisher that evacuates particles of removed contamination from the wire bonding system.

13. The wire bonding system of claim 12, wherein the wire bonding tool includes a capillary and an electronic flame off device.

14. The wire bonding system of claim 10, further comprising at least one of an air guide and a wire tensioner.

15. A method of electrically connecting a first device to a second device, comprising:
passing an insulated wire through a wire bonding system, the insulated wire having a metal core and an insulation material covering the metal core;
identifying a first portion of the insulated wire to be used for formation of a first bond and a second portion of the insulated wire to be used for formation of a second bond;
removing insulation material from the first and second portions of the insulated wire using a wire stripper to expose at least the first and second portions of the metal core;
forming a first bond by wire bonding the exposed metal core of the first portion of the insulated wire to a first bond pad of the first device such that the insulated wire and the first device are electrically connected; and
forming a second bond by wire bonding the exposed metal core of the second portion of the insulated wire to a second bond pad of the second device such that the first device and the second device are electrically connected.

16. The method of claim 15, wherein the wire stripper is one of a micro-clipper and a scrubber.

17. The method of claim 15, further comprising removing insulation material from the first portion of the insulated wire using the wire stripper.

18. A wire bonding system for bonding insulated wire having a metal core and an insulation material covering the metal core, the system comprising:
a wire stripper to which a spool of insulated wire may be coupled, wherein the wire stripper is configured to receive the insulated wire and selectively remove portions of the insulation material from the insulated wire; and
a wire bonding tool that receives the insulated wire having the selected portions of the insulation material removed therefrom from the wire stripper.

19. The wire bonding system of claim 18, wherein the wire stripper is one of a micro-clipper and a scrubber.

20. The wire bonding system of claim 18, wherein the wire bonding tool includes a capillary and an electronic flame off device.
